(19) United States
(12) Patent Application Publication
(10) Pub. No.: US 2026/0351208 A1
(43) Pub. Date: Nov. 5, 2026

(54) ELECTRONIC PAPER DISPLAY, GATE DRIVER ON ARRAY CIRCUIT, AND SINGLE STAGE CIRCUIT THEREOF

(71) Applicant: E Ink Holdings Inc., HSINCHU (TW)

(72) Inventors: Chi-Liang WU, HSINCHU (TW); Wei-Tsung CHEN, HSINCHU (TW); Chia Hao KUO, HSINCHU (TW); Chun Kai CHANG, HSINCHU (TW)

(21) Appl. No.: 19/634,089

(22) Filed: Mar. 31, 2026

Related U.S. Application Data
(60) Provisional application No. 63/798,580, filed on May 2, 2025.

(51) Int. Cl. G09G 3/34

(52) U.S. Cl. CPC G09G 3/344; G09G 2300/0408; G09G 2310/0267; G09G 2330/025

(57) ABSTRACT

A single-stage circuit including input and output units, and an intermediate circuit is provided. The input unit receives set signal and controls first and second nodes to have first and second voltages, respectively. The output unit provides clock signal to output terminal according to first voltage, and blocks system low voltage from output terminal according to second voltage. The intermediate circuit includes three transistors. First and control terminals of first transistor couple system high voltage, and another terminal couples second node. Control terminal of second transistor receives set signal, one terminal couples second node, and another terminal couples system low voltage. Control terminal of third transistor couples first node, one terminal couples second node, and another terminal couples system low voltage. A product of the width-to-length ratio of the first transistor and a positive integer coefficient is smaller than a sum of width-to-length ratios of second and third transistors.

### RELATED APPLICATIONS

This application claims priority to U.S. Provisional Application Ser. No. 63/798,580, filed May 2, 2025, which is herein incorporated by reference.

### BACKGROUND

### Technical Field

The present disclosure relates to display technology, and more particularly to a Gate Driver on Array (GOA) circuit and a single stage circuit thereof suitable for Electronic Paper Display (EPD) technology.

### Description of Prior Art

In Electronic Paper Displays (EPDs), pixel circuits are typically driven by a high voltage to improve the contrast of display particles and the refresh rate. Meanwhile, using Gate Driver on Array (GOA) circuit reduces the costs associated with external gate driver chips.

Since the entire GOA circuit is composed of hundreds or even thousands of cascaded single-stage circuits (depending on the screen resolution) and must operate under high voltage conditions, the potential distribution of various critical nodes within each single stage circuit is crucial. As the operating voltage increases, the current flowing through the components of the single-stage circuit also increases. If the potential distribution among the nodes is uneven or the timing control is poor, this may cause node voltage deviation and generate short circuit currents, resulting in distortion of the output waveforms.

### SUMMARY

Accordingly, the present disclosure provides a single-stage circuit. The single-stage circuit includes an input unit, an output unit, and an intermediate circuit. The input unit is configured to receive a set signal within a set interval, and control a first node to have a first voltage and a second node to have a second voltage in response to the set signal. The output unit is configured to receive a clock signal and a system low voltage, provide the clock signal to an output terminal of the output unit in response to the first voltage, and block the system low voltage from the output terminal in response to the second voltage. The intermediate circuit is coupled between the input unit and the output unit and includes a first transistor, a second transistor, and a third transistor. A first terminal and a control terminal of the first transistor are coupled to a system high voltage, and a second terminal of the first transistor is coupled to the second node. A control terminal of the second transistor receives the set signal, a first terminal of the second transistor is coupled to the second node, and a second terminal of the second transistor is coupled to the system low voltage. A control terminal of the third transistor is coupled to the first node, a first terminal of the third transistor is coupled to the second node, and a second terminal of the third transistor is coupled to the system low voltage. A product of a width-to-length ratio of the first transistor and a coefficient is smaller than a sum of a width-to-length ratio of the second transistor and a width-to-length ratio of the third transistor, and the coefficient is a positive integer.

According to one embodiment of the present disclosure, the coefficient is greater than or equal to 30.

According to one embodiment of the present disclosure, a potential at the second node decreases to the second voltage before a potential at the first node increases to the first voltage.

According to one embodiment of the present disclosure, during a reset interval, the potential of the first node decreases from the first voltage to a third voltage, the potential of the second node increases from the second voltage to a fourth voltage, and the potential of the first node decreases to the third voltage before the potential of the second node increases to the fourth voltage.

According to one embodiment of the present disclosure, during the set interval, the first transistor has a first equivalent impedance, the second transistor has a second equivalent impedance, the third transistor has a third equivalent impedance, and a parallel value of the second equivalent impedance and the third equivalent impedance is significantly smaller than the first equivalent impedance.

According to one embodiment of the present disclosure, the input unit includes a set transistor. A control terminal and a first terminal of the set transistor are coupled to the set signal, and a second terminal of the set transistor is coupled to the first node.

According to one embodiment of the present disclosure, the input unit includes a reset transistor. A control terminal of the reset transistor is coupled to a reset signal, a first terminal of the reset transistor is coupled to the first node, and a second terminal of the reset transistor is coupled to the system low voltage.

According to one embodiment of the present disclosure, the output unit includes a pull-up transistor. A control terminal of the pull-up transistor is coupled to the first node, a first terminal of the pull-up transistor is coupled to the clock signal, and a second terminal of the pull-up transistor is coupled to the output terminal.

According to one embodiment of the present disclosure, the output unit includes a pull-down transistor. A control terminal of the pull-down transistor is coupled to the second node, a first terminal of the pull-down transistor is coupled to the output terminal, and a second terminal of the pull-down transistor is coupled to the system low voltage.

According to one embodiment of the present disclosure, the intermediate circuit further includes a fourth transistor. A control terminal of the fourth transistor is coupled to the second node, a first terminal of the fourth transistor is coupled to the first node, and a second terminal of the fourth transistor is coupled to the system low voltage.

The present disclosure provides an electronic paper display. The electronic paper display includes a display panel and a gate driver on array circuit. The gate driver on array circuit is configured to drive the display panel and includes multiple single-stage circuits as described in any one of the foregoing, and these single-stage circuits are electrically connected in series with each other.

The present disclosure provides a gate driver on array circuit. The gate driver on array circuit includes multiple circuit stages. These circuit stages are electrically connected in series with one another, and each of the circuit stages includes a single-stage circuit as described in any one of the foregoing.

### BRIEF DESCRIPTION OF THE DRAWINGS

For a clearer and easier understanding of the above and other objects, features, advantages, and embodiments of the present disclosure, the drawings are described below.

FIG. 1 is a schematic diagram of an electronic paper display according to an embodiment of the present disclosure.

FIG. 2 is a schematic diagram of an N^{th} single-stage circuit according to an embodiment of the present disclosure.

FIG. 3 is a timing diagram of the states corresponding to a single-stage circuit according to an embodiment of the present disclosure.

FIG. 4 is a schematic diagram of an equivalent circuit of a single-stage circuit during a set interval according to an embodiment of the present disclosure.

FIG. 5 is a schematic diagram of an equivalent impedance model in the set interval based on the equivalent circuit illustrated in FIG. 4.

### DETAILED DESCRIPTION

Various embodiments or examples are provided below for implementing various features of the present disclosure. The embodiments of components and configurations described below are examples only and are not intended to be restrictive. In addition, for the purpose of simplification and clarity, the present disclosure repeats reference numerals and/or numbers in each example in the present disclosure, and this repetition does not in itself limit the relationship between various embodiments and/or components discussed.

In the accompanying figures, the thicknesses of layers, films, panels, and regions are enlarged for clarity. It should be understood that when an element such as a layer, a film, a region, or a substrate is referred to as being “on” or “connected to” another element, it may be directly on or connected to the other element, or intermediate elements may also be present. Conversely, when an element is referred to as being “directly on” or “directly connected to” another element, no intermediate element is present. As used herein, “connection” may refer to physical connection and/or electrical connection. Furthermore, “electrical connection” or “coupling” may refer to the presence of other elements between two elements.

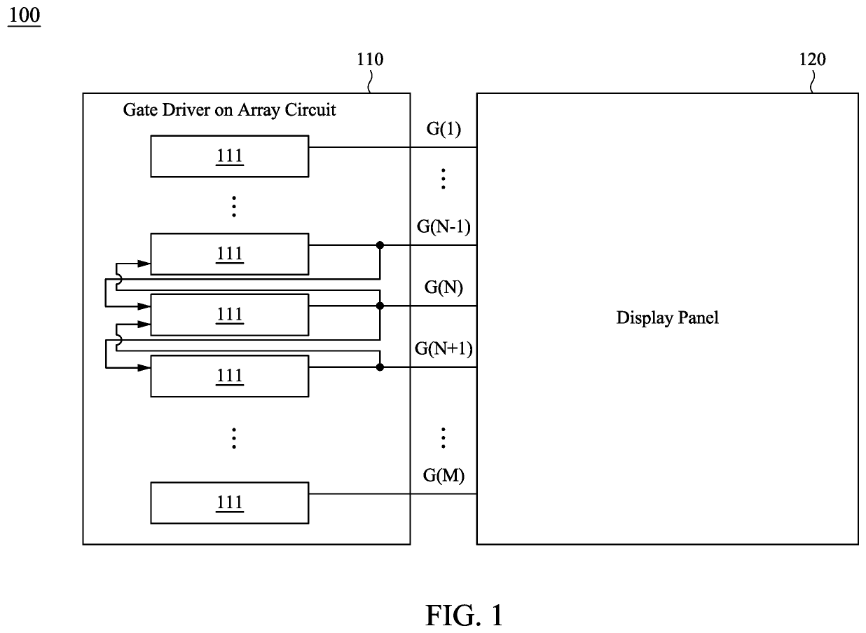

Referring to FIG. 1, FIG. 1 is a schematic diagram of an electronic paper display 100 according to an embodiment of the present disclosure. The electronic paper display 100 includes a Gate Driver on Array (GOA) circuit 110 and a display panel 120. The display panel 120 includes multiple pixel circuits (not shown) arranged in rows and columns. The GOA circuit 110 sequentially supplies multiple scanning signals to multiple columns of pixel circuits on display panel 120, thereby sequentially activating these pixel circuits column by column.

The electronic paper display 100 further includes associated control circuits, such as a data driver circuit (not shown), a timing controller (not shown) and a power supply circuit (not shown). The data driver circuit generates the corresponding data signals based on the input image data. These data signals are then output to the display panel 120 to control the pixel circuits for displaying corresponding grayscales or color levels. The timing controller generates and synchronizes various control signals to coordinate the timing of operations between the GOA circuit 110 and the data driver circuit. The power supply circuit provides multiple voltage levels required for the operations of the circuits, including gate scanning voltages, data voltages, and reference voltages.

With the above configurations, the electronic paper display 100 can perform screen scanning and data writing operations. It can also be used in e-book readers, flexible display devices, and other electrophoretic display technology applications.

The GOA circuit 110 includes cascaded circuit stages. Each circuit stage includes a single-stage circuit 111. The outputs G(1), . . . , G(N−1), G(N), G(N+1), . . . , and G(M) of these single-stage circuits 111 couple to the pixel circuits and sequentially provide the scanning signals to them.

For example, during period N−1, the GOA circuit 110 may provide the scanning signal to the pixel circuit of the (N−1)^{th} column via the output terminal G(N−1) of the (N−1)^{th} single-stage circuit 111. During period N, the GOA circuit 110 may provide the scanning signal to the pixel circuit of the N^{th} column via the output terminal G(N) of the N^{th} single-stage circuit 111.

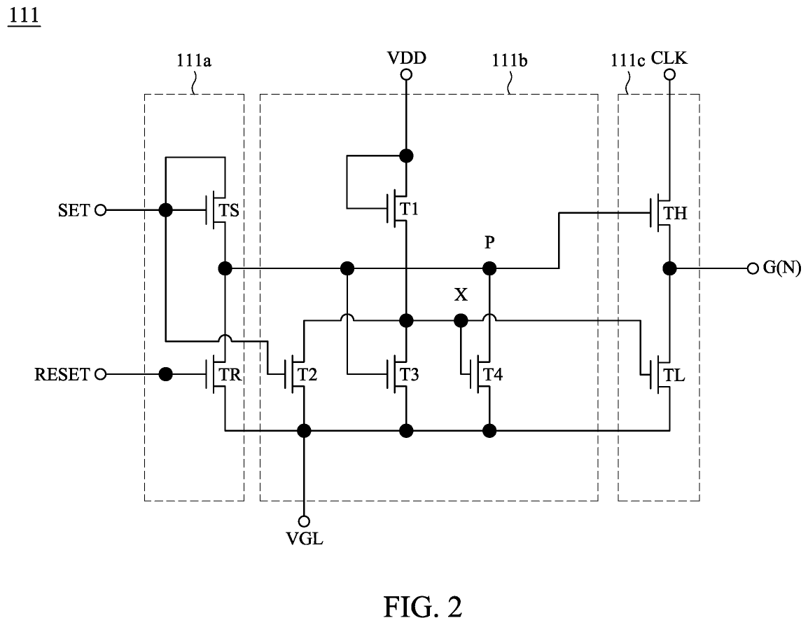

Referring to FIG. 2, FIG. 2 is a schematic diagram of an N^{th} single-stage circuit 111 according to an embodiment of the present disclosure. It should be understood that although FIG. 2 only illustrates the schematic diagram of the N^{th} single-stage circuit 111, the remaining single-stage circuits 111 also possess identical or similar circuit architectures and connection relationships. Therefore, the following description uses the N^{th} single-stage circuit 111 as an exemplary illustration.

The single-stage circuit 111 includes an input unit 111a, an intermediate circuit 111b, and an output unit 111c. The input unit 111a and the output unit 111c couple the first node P and the second node X in the intermediate circuit 111b. The input unit 111a controls the potential changes at the first node P and the second node X based on the received set signal SET or reset signal RESET, causing output unit 111c to response to the potential changes at the first node P and the second node X and output either the clock signal CLK or the system low voltage VGL at the output terminal G(N).

The input unit 111a includes a set transistor TS and a reset transistor TR. During the set interval P_{SET}, the set transistor TS receives the set signal SET (e.g., a high voltage level) and turns on. The potential V_{P} at the first node P attains the high voltage level of the set signal SET due to the conduction of the set transistor TS. During the reset interval PRESET, the reset transistor TR receives the reset signal RESET (e.g., a high voltage level) and turns on. The potential V_{P} at the first node P is pulled down to the system low voltage VGL due to the conduction of the reset transistor TR.

In the application of GOA circuits, the set signal SET may be, for example, the scanning signal output from the preceding circuit stage (i.e., the (N−1)^{th} single-stage circuit 111), while the reset signal RESET may be, for example, the scanning signal output from the subsequent circuit stage (i.e., the (N+1)^{th} single-stage circuit 111).

The output unit 111c includes a pull-up transistor TH and a pull-down transistor TL. During the set interval P_{SET}, since the potential V_{P} of the first node P is at a high voltage level due to the conduction of the set transistor TS, the pull-up transistor TH is turned on accordingly. Upon receiving the clock signal CLK, the pull-up transistor TH provides the clock signal CLK to the output terminal G(N). During the reset interval PRESET, the potential V_{P} of the first node P is at the system low voltage VGL due to the conduction of the reset transistor TR, and the potential V_{X} of the second node X is also raised to a high voltage level. At this time, the pull-up transistor TH is turned off, and the pull-down transistor TL is turned on, thereby outputting the system low voltage VGL to the output terminal G(N).

The intermediate circuit 111b includes a first transistor T1, a second transistor T2, a third transistor T3, and a fourth transistor T4. A first terminal and a control terminal of the first transistor T1 are coupled to the system high voltage VDD, and a second terminal of the first transistor T1 is coupled to the second node X. The first terminal and the control terminal of the first transistor T1 are the drain terminal and the gate terminal, respectively, and both terminals share the same potential. When the system high voltage VDD is applied, the first transistor T1 automatically turns on based on the voltage difference between the gate terminal and the source terminal. This causes the second node X to gradually charge up to a potential close to that of the gate terminal of the first transistor T1.

By connecting the first transistor T1 in a diode configuration, the second node X (i.e., the source terminal of the first transistor T1) is stably biased at the system high voltage VDD when the first transistor T1 receives the system high voltage VDD, thereby preventing unnecessary reverse current or leakage current phenomena.

A control terminal of the second transistor T2 receives the set signal SET, a first terminal of the second transistor T2 is coupled to the second node X, and a second terminal of the second transistor T2 is coupled to the system low voltage VGL. A control terminal of the third transistor T3 is coupled to the first node P, a first terminal of the third transistor T3 is coupled to the second node X, and a second terminal of the third transistor T3 is coupled to the system low voltage VGL. A control terminal of the fourth transistor T4 is coupled to the second node X, a first terminal of the fourth transistor T4 is coupled to the first node P, and a second terminal of the fourth transistor T4 is coupled to the system low voltage VGL.

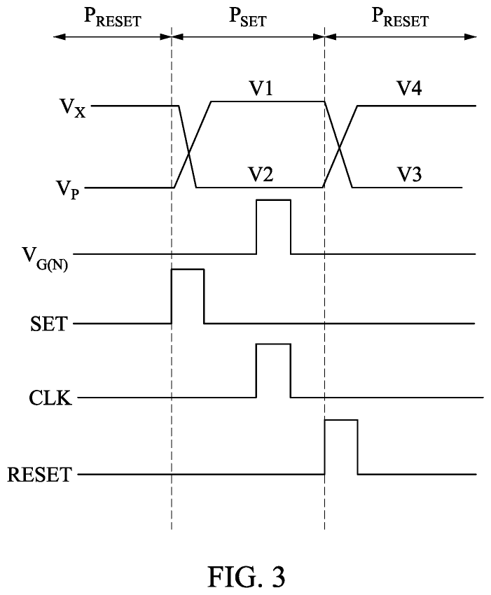

Based on the circuit architecture of the single-stage circuit 111 shown in FIG. 2, the operations of the single-stage circuit 111 in the disclosed embodiment are explained below in conjunction with the timing diagram of the states corresponding to the single-stage circuit 111 illustrated in FIG. 3. In the following, the operational interval of single-stage circuit 111 primarily includes the reset interval PRESET and the set interval P_{SET}.

As shown in FIG. 3, during the set interval P_{SET}, the set transistor TS and the second transistor T2 are turned on by the set signal SET. At this time, the set transistor TS provides the set signal SET to the first node P, causing the potential V_{P} at the first node P to have the first voltage V1. Meanwhile, the second transistor T2 provides the system low voltage VGL to the second node X, causing the potential V_{X} at the second node X to have the second voltage V2.

Correspondingly, the third transistor T3 turns on and provides the system low voltage VGL to the second node X, causing the fourth transistor T4 and the pull-down transistor TL to turn off due to the second voltage V2. By activating the set interval P_{SET}, the pull-up transistor TH turns on due to the first voltage V1 at the first node P. This enables the single-stage circuit 111 to provide the clock signal CLK to output terminal G(N) upon receiving the clock signal CLK, while preventing the system low voltage VGL from being output to terminal G(N).

During the reset interval PRESET, the reset transistor TR turns on upon receiving the reset signal RESET. At this time, the reset transistor TR provides the system low voltage VGL to the first node P, causing the potential V_{P} at the first node P to drop from the first voltage V1 to the third voltage V3, which is approximately equal to the system low voltage VGL. This action turns off the pull-up transistor TH. Additionally, the third transistor T3 turns off to stop providing the system low voltage VGL to the second node X, thereby resetting the potential V_{X} at the second node X from the second voltage V2 to the fourth voltage V4, which is approximately equal to the system high voltage VDD. As a result, the fourth transistor T4 and the pull-down transistor TL are turned on due to the high voltage level of the fourth voltage V4, thereby outputting the system low voltage VGL to the output terminal G(N).

Based on the operating principle above, it is evident that, in addition to ensuring that the third transistor T3 and the pull-up transistor TH remain stably turn on within the set interval P_{SET} based on the potential V_{P} at the first node P, it is also necessary to ensure that the fourth transistor T4 and the pull-down transistor TL remain stably turned off based on the potential V_{X} at the second node X. This prevents the simultaneous conduction of the pull-up transistor TH and the pull-down transistor TL, thereby avoiding leakage currents flowing through the fourth transistor T4 and the pull-down transistor TL.

Therefore, the present disclosure adjusts the width-to-length ratios of the transistors associated with the first node P and the second node X within the single-stage circuit 111 to bring the voltages at the critical nodes closer to the ideal voltage levels. This design achieves the effect of reducing leakage currents and enhancing the reliability of the single-stage circuit 111.

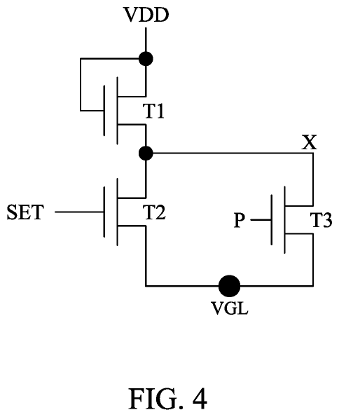

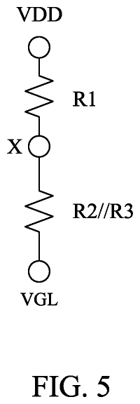

Please refer to FIGS. 4 and 5 simultaneously. FIG. 4 is a schematic diagram of an equivalent circuit of the single-stage circuit 111 during the set interval P_{SET} according to an embodiment of the present disclosure. FIG. 5 is a schematic diagram of an equivalent impedance model in the set interval P_{SET} based on the equivalent circuit illustrated in FIG. 4.

As shown in FIG. 4, the equivalent circuit of single-stage circuit 111 during the set interval P_{SET} primarily consists of the first transistor T1, the second transistor T2, and the third transistor T3. The first transistor T1 forms a pull-up path from the system high voltage VDD to the second node X in a diode connection configuration. The second transistor T2 and the third transistor T3 are connected in parallel. Due to the current-limiting characteristic of the first transistor T1 during conduction and the conduction resistance of the second transistor T2 and the third transistor T3 being controlled by their gate bias voltage and the channel width-to-length ratio, the entire circuit is further equivalent to the impedance model shown in FIG. 5.

As shown in FIG. 5, the first transistor T1 is represented as having a first equivalent impedance R1, the second transistor T2 is represented as having a second equivalent impedance R2, and the third transistor T3 is represented as having a third equivalent impedance R3. The equivalent impedances of the second transistor T2 and the third transistor T3 are regarded as a parallel impedance (R2/R3) of the second equivalent impedance R2 and the third equivalent impedance R3. Therefore, during the set interval P_{SET}, the single-stage circuit 111 may be considered as a series structure formed by the first equivalent impedance R1 and the parallel impedance (R2/R3).

In the disclosed design, the parallel value of the second equivalent impedance R2 and the third equivalent impedance R3 is specifically made significantly smaller than the first equivalent impedance R1, which is expressed as:

(R2/R3)<<R1.

Based on this impedance relationship, the potential V_{X} at the second node X rapidly approaches the low voltage level during the set interval P_{SET}, thereby stably controlling the potential V_{P} at the first node P and the potential V_{X} at the second node X.

Furthermore, to realize the aforementioned impedance relationship in actual circuits, the present disclosure proposes an electrical matching design approach by adjusting the width-to-length ratio of the first transistor T1, the second transistor T2 and the third transistor T3 (i.e. the ratio of channel width (W) to channel length (L)). In the disclosed embodiment, the product of the width-to-length ratio of the first transistor T1 and a coefficient k is less than the sum of the width-to-length ratios of the second transistor T2 and the third transistor T3. This design relationship is expressed as:

$$k \times {( \frac{W}{L} )}_{T 1} = {( \frac{W}{L} )}_{T 2} + {( \frac{W}{L} )}_{T 3} .$$

In the above relationship, the coefficient k is a positive integer. When the coefficient k is greater than or equal to 30, it ensures that the steady-state voltages of the first node P and the second node X during the set interval P_{SET} approach the ideal driving conditions. This effectively prevents leakage currents caused by the simultaneous conduction of the pull-up transistor TH and the pull-down transistor TL, thereby stabilizing the output waveforms at the output terminal G(N) of the single-stage circuit 111.

For example, if the channel width of the first transistor T1 is set to 5 micrometers (μm) and the channel length to 45 μm; the channel width of the second transistor T2 is set to 80 μm and the channel length to 10 μm; and the channel width of the third transistor T3 is set to 80 μm and the channel length to 10 μm; then the coefficient k is approximately 160. Therefore, the design conditions of the coefficient k being greater than or equal to 30 has been met, ensuring that the potentials at the first node P and the second node X approach the ideal potentials and that the driving waveforms at the output terminal G(N) remain stable and undistorted.

Conversely, if the coefficient k is less than 30, the difference in conduction capability between the first transistor T1 and the second and third transistors T2, T3 becomes excessively large. Therefore, the second node X may fail to complete potential transition within the prescribed timing, and the first node P may undergo incomplete discharge due to a control delay of the third transistor T3. Under these circumstances, the clock signal CLK outputted to the output terminal G(N) exhibits distortion or edge delay, thereby affecting the scanning operations of the subsequent stage pixel circuits.

Referring again to FIG. 3, the waveforms of the potential V_{P} at the first node P and the potential V_{X} at the second node X show that, during the set interval P_{SET} and reset interval PRESET, the voltages change at both nodes and exhibit a controlled slope difference and timing relationship based on the width-to-length ratio design of the first transistor T1, the second transistor T2, and the third transistor T3 disclosed herein.

During the set interval P_{SET}, since the parallel conduction capability of the second transistor T2 and the third transistor T3 exceeds that of the first transistor T1, the potential V_{X} at the second node X rapidly drops from the high voltage level to the second voltage V2 first. Subsequently, the potential V_{P} at the first node P rises to the first voltage V1. This time difference ensures that the second node X stabilizes at the low voltage level before the first node P fully rises to the target voltage, thereby preventing leakage currents or cross-conduction caused by instantaneous conduction.

In contrast, during the reset interval PRESET, the conduction capabilities of the first transistor T1, the second transistor T2, and the third transistor T3 cause the potential change to exhibit opposite trends. At this time, the potential V_{P} at the first node P gradually decreases from the first voltage V1 to a third voltage V3, while the potential V_{X} at the second node X slowly increases from the second voltage V2 to a fourth voltage V4. Since the falling slope of the potential V_{P} at the first node P is greater than the rising slope of the potential V_{X} at the second node X, the first node P has already fully dropped to the third voltage V3 before the second node X reaches the fourth voltage V4.

The sequential relationship between the potential slopes of the first node P and the second node X ensures the accuracy and integrity of the output waveforms during the set interval P_{SET} and reset interval PRESET, respectively, thereby enabling the normal operations of the single-stage circuit 111.

In conclusion, the electronic paper display, the GOA circuit, and the single-stage circuit thereof disclosed herein perform parameter adjustments on the transistors associated with the critical nodes. By designing the channel width-to-length ratios and the equivalent impedance ratios of the first transistor, the second transistor, and the third transistor, the disclosed design effectively stabilizes the potentials of the critical nodes. Based on the design of the present disclosure, the potentials of the critical nodes maintain appropriate slopes and timing differences during the set interval and the reset interval. This configuration avoids leakage currents caused by simultaneous conduction of the pull-up and pull-down transistors, and ensures the stability of the waveforms outputted by the output terminal, thereby enhancing the driving stability and display quality of the electronic paper display.

Although the present disclosure has been disclosed as above in embodiments, the embodiments are not intended to limit the present disclosure, and those of ordinary skill in the art may make some changes and embellishments within the spirit and scope of the present disclosure, therefore, the scope of protection of the present disclosure shall be defined in the attached claims.

What is claimed is:

1. A single-stage circuit, comprising:
an input unit configured to receive a set signal within a set interval, and control a first node to have a first voltage and a second node to have a second voltage in response to the set signal;
an output unit configured to receive a clock signal and a system low voltage, provide the clock signal to an output terminal of the output unit in response to the first voltage, and block the system low voltage from the output terminal in response to the second voltage; and
an intermediate circuit coupled between the input unit and the output unit and comprising:
a first transistor, wherein a first terminal and a control terminal of the first transistor are coupled to a system high voltage, and a second terminal of the first transistor is coupled to the second node;
a second transistor, wherein a control terminal of the second transistor receives the set signal, a first terminal of the second transistor is coupled to the second node, and a second terminal of the second transistor is coupled to the system low voltage; and
a third transistor, wherein a control terminal of the third transistor is coupled to the first node, a first terminal of the third transistor is coupled to the second node, and a second terminal of the third transistor is coupled to the system low voltage;
wherein a product of a width-to-length ratio of the first transistor and a coefficient is smaller than a sum of a width-to-length ratio of the second transistor and a width-to-length ratio of the third transistor, and wherein the coefficient is a positive integer.

2. The single-stage circuit of claim 1, wherein the coefficient is greater than or equal to 30.

3. The single-stage circuit of claim 1, wherein a potential at the second node decreases to the second voltage before a potential at the first node increases to the first voltage.

4. The single-stage circuit of claim 3, wherein during a reset interval, the potential of the first node decreases from the first voltage to a third voltage, the potential of the second node increases from the second voltage to a fourth voltage, and the potential of the first node decreases to the third voltage before the potential of the second node increases to the fourth voltage.

5. The single-stage circuit of claim 1, wherein during the set interval, the first transistor has a first equivalent impedance, the second transistor has a second equivalent impedance, the third transistor has a third equivalent impedance, and a parallel value of the second equivalent impedance and the third equivalent impedance is significantly smaller than the first equivalent impedance.

6. The single-stage circuit of claim 1, wherein the input unit comprises:
a set transistor, wherein a control terminal and a first terminal of the set transistor are coupled to the set signal, and a second terminal of the set transistor is coupled to the first node.

7. The single-stage circuit of claim 6, wherein the input unit comprises:
a reset transistor, wherein a control terminal of the reset transistor is coupled to a reset signal, a first terminal of the reset transistor is coupled to the first node, and a second terminal of the reset transistor is coupled to the system low voltage.

8. The single-stage circuit of claim 1, wherein the output unit comprises:
a pull-up transistor, wherein a control terminal of the pull-up transistor is coupled to the first node, a first terminal of the pull-up transistor is coupled to the clock signal, and a second terminal of the pull-up transistor is coupled to the output terminal.

9. The single-stage circuit of claim 8, wherein the output unit comprises:
a pull-down transistor, wherein a control terminal of the pull-down transistor is coupled to the second node, a first terminal of the pull-down transistor is coupled to the output terminal, and a second terminal of the pull-down transistor is coupled to the system low voltage.

10. The single-stage circuit of claim 1, wherein the intermediate circuit further comprises:
a fourth transistor, wherein a control terminal of the fourth transistor is coupled to the second node, a first terminal of the fourth transistor is coupled to the first node, and a second terminal of the fourth transistor is coupled to the system low voltage.

11. An electronic paper display, comprising:
a display panel; and
a gate driver on array circuit configured to drive the display panel and comprising:
a plurality of single-stage circuits, wherein the plurality of single-stage circuits are electrically connected in series with each other, and each of the plurality of single-stage circuits comprises:
an input unit configured to receive a set signal within a set interval, and control a first node to have a first voltage and a second node to have a second voltage in response to the set signal;
an output unit configured to receive a clock signal and a system low voltage, provide the clock signal to an output terminal of the output unit in response to the first voltage, and block the system low voltage from the output terminal in response to the second voltage; and
an intermediate circuit coupled between the input unit and the output unit and comprising:
a first transistor, wherein a first terminal and a control terminal of the first transistor are coupled to a system high voltage, and a second terminal of the first transistor is coupled to the second node;
a second transistor, wherein a control terminal of the second transistor receives the set signal, a first terminal of the second transistor is coupled to the second node, and a second terminal of the second transistor is coupled to the system low voltage; and
a third transistor, wherein a control terminal of the third transistor is coupled to the first node, a first terminal of the third transistor is coupled to the second node, and a second terminal of the third transistor is coupled to the system low voltage;
wherein a product of a width-to-length ratio of the first transistor and a coefficient is smaller than a sum of a width-to-length ratio of the second transistor and a width-to-length ratio of the third transistor, and wherein the coefficient is a positive integer.

12. The electronic paper display of claim 11, wherein the coefficient is greater than or equal to 30.

13. The electronic paper display of claim 11, wherein a potential at the second node decreases to the second voltage before a potential at the first node increases to the first voltage.

14. The electronic paper display of claim 13, wherein during a reset interval, the potential of the first node decreases from the first voltage to a third voltage, the potential of the second node increases from the second voltage to a fourth voltage, and the potential of the first node decreases to the third voltage before the potential of the second node increases to the fourth voltage.

15. The electronic paper display of claim 11, wherein during the set interval, the first transistor has a first equivalent impedance, the second transistor has a second equivalent impedance, the third transistor has a third equivalent impedance, and a parallel value of the second equivalent impedance and the third equivalent impedance is significantly smaller than the first equivalent impedance.

16. The electronic paper display of claim 11, wherein the input unit comprises:
a set transistor, wherein a control terminal and a first terminal of the set transistor are coupled to the set signal, and a second terminal of the set transistor is coupled to the first node.

17. The electronic paper display of claim 16, wherein the input unit comprises:
a reset transistor, wherein a control terminal of the reset transistor is coupled to a reset signal, a first terminal of the reset transistor is coupled to the first node, and a second terminal of the reset transistor is coupled to the system low voltage.

18. The electronic paper display of claim 11, wherein the output unit comprises:
a pull-up transistor, wherein a control terminal of the pull-up transistor is coupled to the first node, a first terminal of the pull-up transistor is coupled to the clock signal, and a second terminal of the pull-up transistor is coupled to the output terminal.

19. The electronic paper display of claim 18, wherein the output unit comprises:
a pull-down transistor, wherein a control terminal of the pull-down transistor is coupled to the second node, a first terminal of the pull-down transistor is coupled to the output terminal, and a second terminal of the pull-down transistor is coupled to the system low voltage.

20. A gate driver on array circuit, comprising:
a plurality of circuit stages, wherein the plurality of circuit stages are electrically connected in series with one another, and each of the circuit stages comprises a single-stage circuit, the single-stage circuit comprises:
an input unit configured to receive a set signal within a set interval, and control a first node to have a first voltage and a second node to have a second voltage in response to the set signal;
an output unit configured to receive a clock signal and a system low voltage, provide the clock signal to an output terminal of the output unit in response to the first voltage, and block the system low voltage from the output terminal in response to the second voltage; and
an intermediate circuit coupled between the input unit and the output unit and comprising:
a first transistor, wherein a first terminal and a control terminal of the first transistor are coupled to a system high voltage, and a second terminal of the first transistor is coupled to the second node;
a second transistor, wherein a control terminal of the second transistor receives the set signal, a first terminal of the second transistor is coupled to the second node, and a second terminal of the second transistor is coupled to the system low voltage; and
a third transistor, wherein a control terminal of the third transistor is coupled to the first node, a first terminal of the third transistor is coupled to the second node, and a second terminal of the third transistor is coupled to the system low voltage;
wherein a product of a width-to-length ratio of the first transistor and a coefficient is smaller than a sum of a width-to-length ratio of the second transistor and a width-to-length ratio of the third transistor, and wherein the coefficient is a positive integer.
